(19) United States
(12) Patent Application Publication
(10) Pub. No.: US 2002/0144783 A1
(43) Pub. Date: Oct. 10, 2002

(54) Apparatus and method for accelerating process stability of high temperature vacuum processes after chamber cleaning

(75) Inventors: Truc Tran, Fremont, CA (US); Ramanujapuram Anandampillai Srinivas, San Jose, CA (US); Hong Bee Teoh, Saratoga, CA (US); A vgerinos Jerry Gelatos, Redwood City, CA (US); Marlon Edward Menezes, Campbell, CA (US); Vicky Uyen Nguyen, San Jose, CA (US); Yehuda Demayo, San Jose, CA (US); Rommel Ruiz, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/827,877

(22) Filed: Apr. 5, 2001

(51) Int. Cl. C23F 1/00; C03C 25/68; H01L 21/302

(52) U.S. Cl. 156/345.33; 216/67; 438/710

(57) ABSTRACT

A structure and method which substantially reduce the number of run-in substrates that have to be used in a high temperature (550° C. or greater) processing environment is presented. A barrier to conductive heat transfer is provided between a process gas distribution faceplate and its process chamber support. This allows the gas distribution faceplate to thermally float and substantially reduces the temperature transients in the faceplate, which can cause thermal (temperature) transients when wafer processing is begun. The present configuration uses a thermal separation assembly to substantially block conductive heat transfer to the cold processing chamber, by using a Vespel gasket or stainless steel washers and thereby reduces the thermal gradient experienced by the gas distribution faceplate. As a result of the improved thermal uniformity, the number of run-in wafer that need to be used is reduced by 80 to 95%.

### BACKGROUND OF THE INVENTION

1. Field Of The Invention

This invention relates to an apparatus and method for reducing the time necessary to achieve stable process conditions in a vacuum processing chamber used to process substrates. More particularly it relates to reducing the time needed to achieve stable etch process conditions in a vacuum processing chamber being used for etching of semiconductor wafers at temperatures in excess of 600° C., after the chamber has been (wet) cleaned.

2. Background of the Invention

The use of vacuum processing chambers for the processing (deposition and etch) of substrates (wafers) includes process monitoring to assure that product quality is met. Whether in deposition of etch processes, the process condition are such that after a period of time (which can be equated to the number of wafers processed) the process chamber has to be taken out of service for cleaning or renewal. Once the renewal or cleaning process is complete the chamber is closed up checked for leaks, and vacuum conditions are initiated. In processes involving high temperatures, passive sources of thermal energy such as electrical heating elements are energized to bring the process chamber components to temperatures at or near the actual operating conditions. Once the conditions necessary for initiating processing have been reached, substrate processing is begun. The first substrates (wafers) sent through the chamber are identified as “run-in” wafers. The properties of the “run-in” wafers are monitored until measurements of substrate properties resulting from the processing are acceptable and are stable. One of these measurement is sheet (film) resistance. Such a measurement is usually made by measuring such sheet resistance simultaneously at 49 points on the wafer. When uniform processing is a process requirement, the deviation of any one measurement is compared to the mean of the set of points measured and uniformity is not considered acceptable until a statistically proven range of acceptability is reached. Curve 200 in FIG. 8 shows an approximation of the quantitative evaluation of numbers of “run-in” substrates initiated after process conditions are reached after a wet clean of an etch processing chamber, as those properties progress to a stable value as shown by horizontal line 202.

The curve 200 approximates the data from a high temperature etch processing chamber used for titanium metal etching. The chamber is wet cleaned, sealed, and then a vacuum is pulled as the temperature of the chamber is increased to at or near the processing temperature of 650° C. Experience shows that the thermal transient associated with heating to process ready conditions takes about 3 to 5 hours. Once the chamber thermal and vacuum conditions are considered to be process ready, then wafer run-in occurs. The wafers being run are exposed to “normal” steady state process conditions—established by previous operation of the chamber based on a long term evaluation. Selected wafer properties such as surface resistance and/or film thickness are subsequently measured directly or indirectly (such a by using optical measurements whose correlation to surface qualities is known) regularly and the use of “run-in” wafers is continued until wafers being run through the process are measured to have the desired surface properties. Then processing of “normal” wafers can continue. As can be seen by curve 200 of FIG. 8, the number of “run-in” wafers that need to be run through the process chamber to pass from a zone of transient conditions into a zone of steady state conditions is approximately 100. Since processing each wafer takes anywhere from several seconds to several minutes, the time to process 100 wafers to achieve steady state processing of the wafers creates a further delay (more than just achieving desired thermal and vacuum conditions and stability) in initiating production processing of substrates (wafers). In a high temperature process, this delay can add more than an hour to the time that is takes a chamber to recover from a wet clean. To improve production efficiency it is desirable to reduce the number of “run-in” wafers that it takes to pass through the transient associated with processing “run-in” wafers and achieve steady state processing of wafers.

### SUMMARY OF THE INVENTION

This invention relates to an apparatus and method which completely unexpectedly and to a substantial degree reduces the number of “run-in” wafers that need to be run to achieve wafer-to-wafer processing stability (where processing of a second wafer, processed after a first wafer processed under the same processing conditions in that chamber, results in a substantially similar alteration of selected surface characteristics of the of the second wafer as occurred for the first wafer). The invention involves separating the gas distribution faceplate (showerhead) from its support. This separation seems to act as a substantial thermal block to prevent heat transfer between the gas distribution faceplate and its cooled support while still maintaining a secure electrical contact so that the gas distribution faceplate can still act as one of two electrodes which provide an RF field which causes the gas in the region of the electrical field to form a plasma.

The apparatus according to the invention includes an etch processing chamber or etch processing chamber for processing substrates at temperatures in excess of 550° C. (in actual operation being approximately 650° C.) having a heater having a substrate support surface on which a back side of the substrate to be etched is supported during etching of a front side of the substrate; a gas box cavity in a portion of the etch processing chamber, the cavity being disposed opposite the substrate support surface of the heater; a gas distribution faceplate disposed between the gas box cavity and the substrate support surface of the heater, the faceplate having gas distribution holes therein to permit the passage of gas therethrough, and a separation member or a thermally insulating connection assembly fixing the gas distribution faceplate to the etch processing chamber while providing a substantially minimal transfer of thermal energy by conductive heat transfer between the faceplate and the etch chamber.

The separation member or the thermally insulating connection assembly can be a series of shims clamped at selected locations between the gas distribution faceplate and the etch processing chamber, wherein the shims act as spacers separating the gas distribution faceplate from the etch processing chamber. The shims can be stainless steel washers clamped at selected intervals around a perimeter of the gas distribution faceplate.

The separation member or the thermally insulating connection assembly can be a polymer based gasket clamped between the gas distribution faceplate and the etch processing chamber, where the gasket acts as a spacer separating the gas distribution faceplate from the etch processing chamber. The gasket can be made of a material having material properties substantially similar to Vespel. The gasket can have thicknesses which range between 0.010 and 0.030 inches and in one embodiment is selected to be approximately 0.018 inches.

A method according to the invention for reducing the number of run-in substrates needed to arrive at steady state process conditions in a high temperature etch processing chamber includes the steps of: providing a separation member between a gas distribution faceplate and a surface of the processing chamber to which it is clamped; clamping the gas distribution faceplate to the surface of the processing chamber so as to create a separation distance between the gas distribution faceplate to the surface of the processing chamber; preheating the processing chamber to a near etch process temperature; and processing no more than selected maximum numbers of run-in substrates (such as 25, 20, 15, 10, and 5) before confirming the uniformity of etch process operation in the high temperature processing chamber. The step of providing the separation member includes providing shims at selected locations between the faceplate and the surface of the processing chamber, or providing a polymer based material gasket between the faceplate and the surface of the processing chamber, where the polymer based material is a material having properties substantially similar to Vespel.

The use of the apparatus and method according to the invention provides a substantial improvement over the previous arrangement, in that only three to five wafers need to be used for the “run-in” which is a substantial reduction from the approximately 100 that needed to be used previously and as such is completely unexpected.

### BRIEF DESCRIPTION OF THE DRAWINGS

FIG. 1 is a schematic cross sectional view of a portion of the process chamber without use of a configuration according to the invention;

FIG. 2 is schematic representation of the configuration of a processing chamber as presented in FIG. 1, which highlights the flow of thermal energy;

FIG. 3 is a plot of temperature with respect to position in the gas distribution face plates as shown in FIGS. 1 and 2 and a top view of which is shown in the upper portion of FIG. 3, such that the plot of temperature at the bottom of FIG. 3 correlates to the position at which the temperature is represented across a diameter of the gas distribution faceplate;

FIG. 4 is a schematic cross sectional view of a portion of a processing chamber similar to that shown in FIG. 1, including a configuration according to the invention;

FIG. 5 is a top view of a Vespel gasket which can be employed in one embodiment of a configuration according to the invention;

FIG. 6 is a top view of a series of washers disposed in a regular pattern which can be employed in a second embodiment of a configuration according to the invention;

FIG. 7 is a plot of temperature with respect to position in the gas distribution face plates as shown in FIG. 4 and a top view of which is shown in the upper portion of FIG. 7, such that the plot of temperature at the bottom of FIG. 7 correlates to the position at which the temperature is represented across a diameter of the gas distribution faceplate; and

FIG. 8 shows two plots showing the correlation between the wafer to wafer parameter being measured to check for wafer to wafer process uniformity on the Y axis and the number of wafer processed after a wet clean on the X axis.

### DETAILED DESCRIPTION OF THE PREFERRED EMBODIMENT

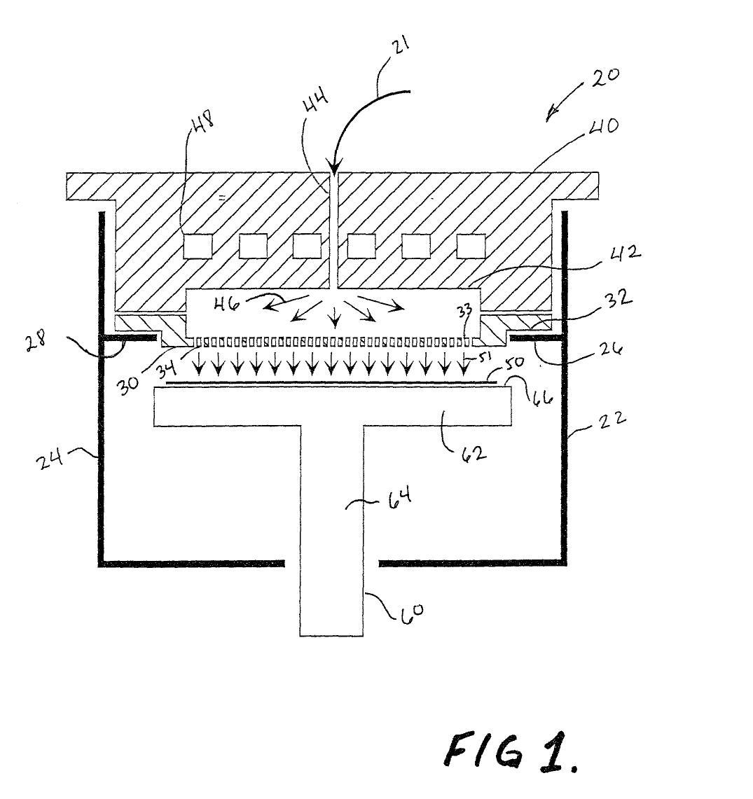

FIG. 1 shows a schematic view of a high temperature etch processing chamber 20. The bottom and side walls of the chamber 20 are represented by two heavy “L” shaped lines 22, 24. In general the upper body portion 40 of the processing chamber 20 is electrically isolated from the bottom and side walls so that an electrical bias can be created between the two. The “L” shaped lines 22, 24 therefore represent several types of materials even though only one structure is shown. Two horizontal lines 26, 28 represent chamber internal insulating members (preferably ceramic rings) which overlap the outer flange 32 of the gas distribution plate 30, so that screw heads of screws (not shown) clamping the gas distribution plate 30 to the upper body portion 40 are covered by the internal insulating members, represented by the lines 26, 28 and are not directly exposed to plasma in the processing chamber 20.

A heater 60 (a disk shaped member 62 supported from the back by a stem 64) has an electrical resistor heater core (not shown) embedded therein for heating the inside of the processing chamber 20 in the absence of plasma. The top surface 66 of the heater 60 is considered to be its substrate support surface.

A wafer (or substrate to be processed) 50 is supported on its back side by the heater 60 during plasma processing. The wafer 50 is disposed opposite the faceplate 34 of the gas distribution plate 30. The faceplate contains numerous small holes (only some of which are represented by the holes shown) 33 to cause the gas in a gas box cavity 42 to be distributed substantially uniformly over the front surface area of the wafer 50 which is facing the gas distribution faceplate 34. Process gas is supplied to a gas supply passage 44 as represented by the arrow 21. A gas plenum is created between the gas box cavity 42 into which the process gas exhausts (as represented by the arrows 46) and the back side of the gas distribution plate 30. The outer flange 32 of the gas distribution plate is clamped to a corresponding surface of the upper body portion 40 by connecting screws which are not shown. Gas exiting from the gas distribution faceplate 34 is generally uniformly directed toward the wafer being processed as represented by the arrows 51.

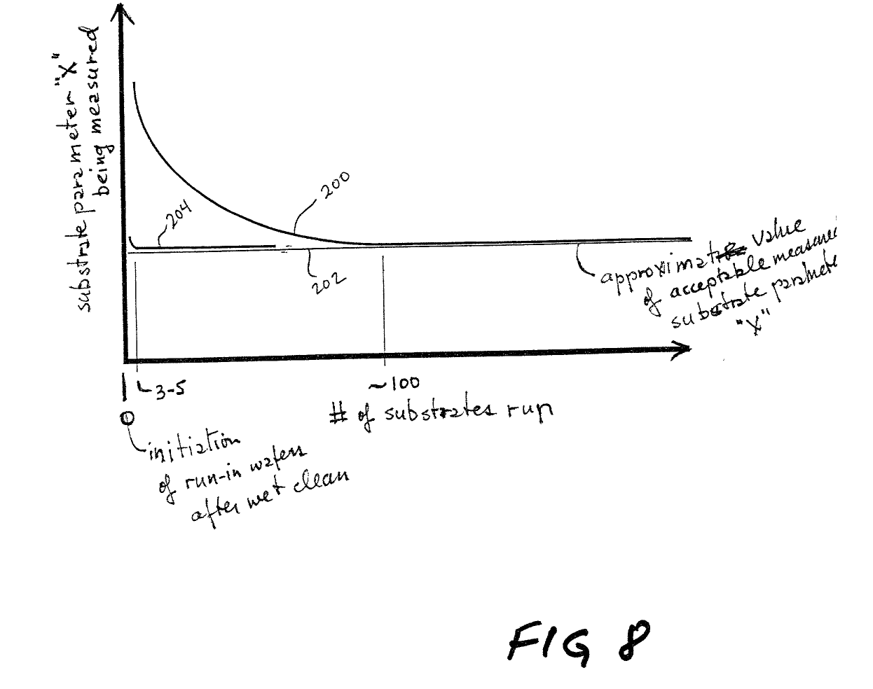

The gas distribution plate 30 is generally machined from a nickel alloy, while the upper body portion 40 of the process chamber 20 is made of aluminum. Process temperatures in titanium etch chambers of the type illustrated are set at 650° C. At such a high temperature there is a substantial amount of thermal energy that must be dissipated to keep surrounding structures at reasonable temperatures. Cooling channels 48 in the upper body portion 40 of the processing chamber keep the temperature of the upper body portion in the range of 50° to 70° C. The 650° C. process temperature exists in the processing chamber at the top surface of the wafer being processed 50, the source of thermal energy is the heater element embedded in the heater 60 and the plasma that forms due to the RF field created between the gas distribution plate 30, which acts as one RF electrode and a second electrode embedded in the heater 60 (separate from the heater core also embedded there) in the region between the wafer 50 and the gas distribution plate 30 generally occupied by the arrows 51. The gas distribution plate 30 must have an electrically secure connection to the upper body portion 40 to maintain its status as an electrode on one side of the RF field which maintains the plasma in the process chamber. With these basic elements in mind, the number of run in wafers that needed to be processed to achieve wafer to wafer process stability was approximately 100 after a wet clean had been completed, as discussed above in the background of the invention, where curve 200 of FIG. 8 was discussed.

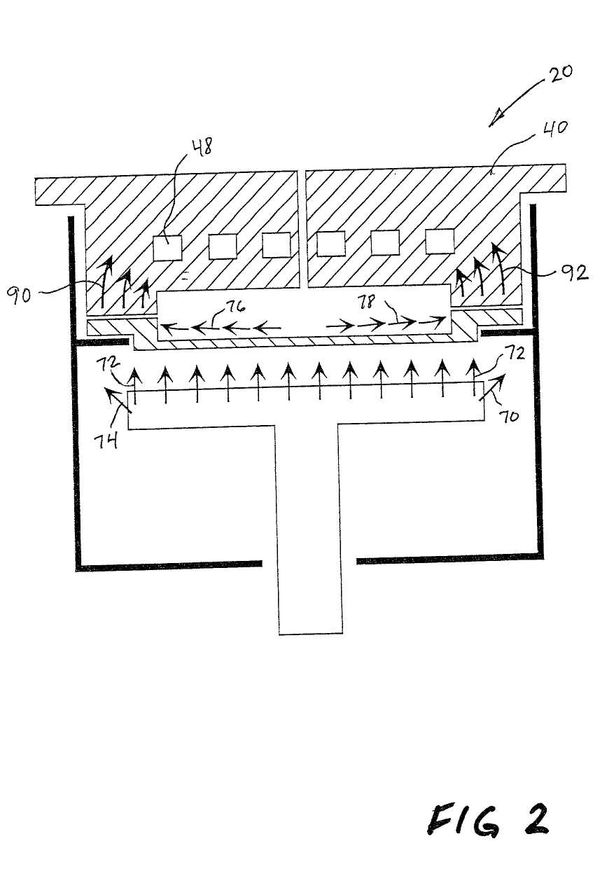

FIG. 2 shows a slightly modified cross sectional view of the process chamber 20 as shown in FIG. 1. The configuration shown represents the portion of the chamber heating up process that is present once the wet clean is complete and before the processing of “run in” wafers takes place. The small holes 33 in the faceplate 34 are omitted in this view. In this heating up condition the only source of thermal energy is from the heating element in the disk shaped member 62 of the heater 60. The transfer of thermal energy from the heater toward to upper portion of the chamber is represented by the series of arrows from 70, through the whole series identified as 72, and ending at 74. The high temperature of the heater causes the temperature of all components around and close to the heater to rise. The component that is closest to the heater in this context is the gas distribution faceplate 30. As the temperature of the surface of the faceplate closest to the heater becomes hot, the thermal energy transferred to the faceplate causes a rise in the temperature of the faceplate. As the temperature of the faceplate rises the temperature differential between the high temperature faceplate and the low temperature upper body portion 40 which is cooled by thermal transfer liquid, such as water flowing through thermal transfer passages (cooling channels) 48 which act as a heat sink to hold the temperature of the upper body portion to about 50-70° C., which is substantially less that the temperature of the heater body 60 whose temperature is approaching 650° C. in preparation for providing stable process conditions at 650° C. The temperature differential provides flow of thermal energy by conductive heat transfer from regions having high temperatures to regions having low temperatures. The flow of thermal energy (thermal flux) is represented by sets of horizontal arrows 76, 78 illustrating the thermal flux flowing in the material of the gas distribution plate 30, from the center of the gas distribution plate 30 outwards to the left and the right, respectively. Another two sets of three each vertically oriented arrows 90, 92 represent the heat flux flowing from the region of the outer flange 32 of the gas distribution plate 30 through the surface of the upper body portion 41 mating with the outer flange 32. The heat flux is from the high temperature outer flange 32 to the low temperature thermal transfer liquid in the cooling passages 48.

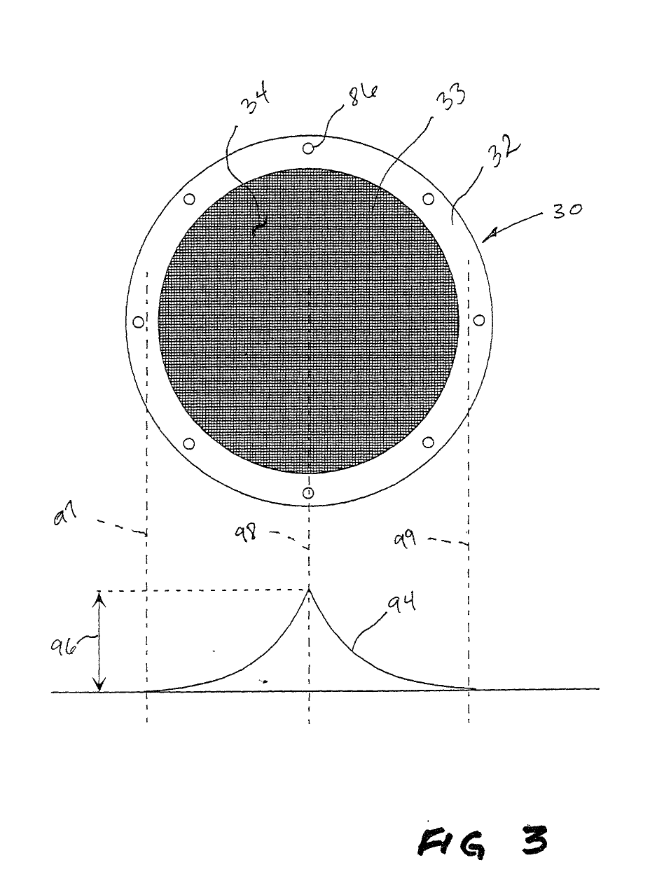

FIG. 3 shows a top view of the gas distribution plate 30. The plate 30 includes the faceplate section 34, which has numerous small holes 33 to provide gas distribution therethrough, and the outer flange section 32 which is attached to the upper body portion 40. A graph of the location across a diameter of the gas distribution plate 30 versus the relative temperature at such a location corresponding to the gas distribution plate 30 shown in the upper portion of FIG. 3, is shown by the curve 94. The vertical dimensioning arrow 96 represents the peak value of temperature which corresponds to the center of the faceplate section 34. Horizontal correlation of the relative values shown on the curve 96 are shown by the dashed lines 97, 98, 99 which correspond to the relative location of the temperature magnitude at those locations with a gradual transient as shown by the curve 96. The center peak of the curve 96, while shown as a pointed peak, can also be considered to be a rounded peak. However since the curve 96 provides only an illustration of relative values the trend and not the actual peak value is what is worthy of note. The curve 96 provides an abrupt if not sudden transition from a high temperature at the center of the faceplate section 34, to a low temperature at the location near the middle of the outer flange 32 where the outer flange is clamped to the upper body portion 40. At approximately the middle of the outer flange 32, conductive heat transfer provides a maximum heat flux to the upper body portion 40 from which thermal energy is removed at a high rate by the thermal transfer liquid circulating thought its cooling channels.

The gas distribution plate 30 shown in FIG. 3 includes a series of flange bolt holes (i.e., 86) through which threaded fasteners having screw or bolt heads (not shown) are extended and tightened to clamp the gas distribution plate 30 to the upper body portion 40, as seen in FIG. 2. The clamping force generated by the bolts (not shown) clamps the full face of the outer flange to a matching flange receiving face on the bottom of the upper body portion 40 so that substantially the whole of the area of the outer flange 32 is in close proximity to, if not in clamped contact with its facing surface. This clamped and close contact provides substantial area for conductive heat transfer across the clamped joint. The clamped surfaces and bolt connections also provide electrical continuity between the gas distribution plate 30 and the upper body portion so that the faceplate section 34 can continue to act as an electrode in an RF plasma enhanced process.

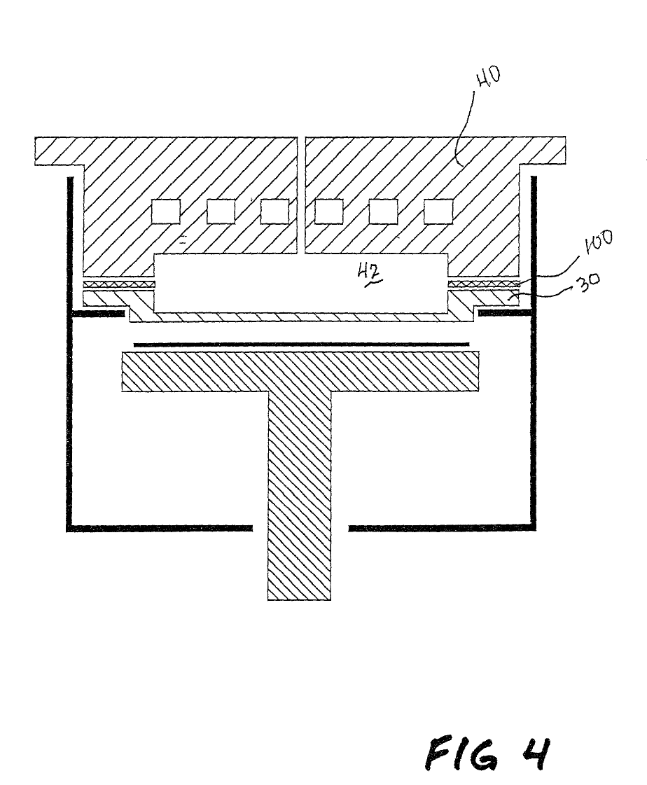

FIG. 4 shows a cross sectional view of a substrate processing chamber, similar to that shown in FIG. 2, except that an embodiment according to the invention is shown incorporated in the clamped joint (thermally insulating connection assembly) between the gas distribution plate 30 and the upper body portion 40. One configuration of an embodiment according to the invention provides a separating member (or means) 100 to separate the gas distribution plate 30 from the upper body portion 40, while still remaining clamped thereto and having electrical continuity between the two provided by the previously mentioned clamping bolts that are not shown.

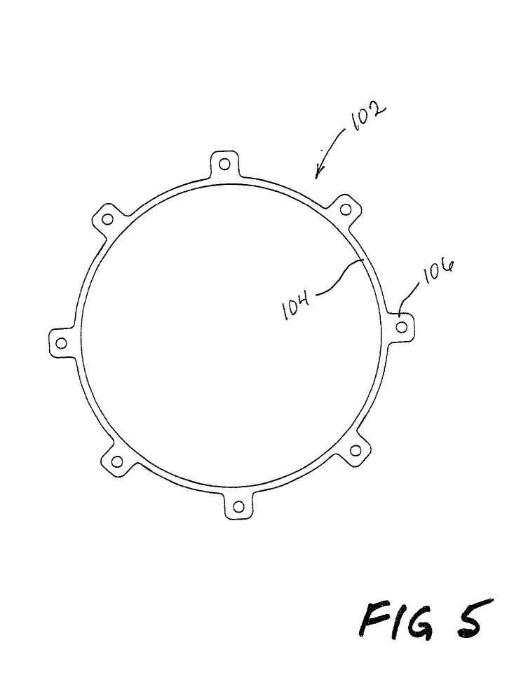

One configuration of a separating member 100 is a polymer based material, having properties substantially similar to the material identified with the tradename Vespel™. A gasket 102 made of such material is configured as shown in FIG. 5. An internal ring portion 104 of the gasket provides a loop seal, or barrier, to prevent or reduce the amount of flow from the inside the gas box cavity 42 sideways through the clamped joint. A series of tabs 106 (which act as a series of shims) extend outwardly from the ring portion 104. Each tab has a hole for receiving a bolt for locating the gasket with respect to the outer flange 32 bolt holes and through which bolts (not shown—and usually made of a nickel alloy) clamping the gasket between the outer flange 32 of the gas distribution plate and the corresponding mating surface of the upper body portion. The tabs 106 create a clamping pad around each bolt (not shown) clamping the gas distribution plate 30 to the upper body portion 40 and create a separation distance between the gas distribution plate 30 and the upper body portion 40. That separation distance being the thickness of the clamped Vespel™ gasket 102. A thickness of the Vespel™ gasket conducive to a configuration using the invention has been found to be 0.018 inches (0.457 mm). The thickness for useful operation may vary between 0.010 and 0.030 inches. The Vespel™ gasket material is selected for its resistance to deterioration when exposed to temperatures in excess of 550° C. and as high as 650° C. and for its resistance to conductive heat transfer. When using lower temperature processes other insulating materials, appropriate for the chemical and temperature environment can be chosen, though in lower temperature environments the beneficial effect (degree of improvement achieved by the invention (reduced run-in time) may be lessened.

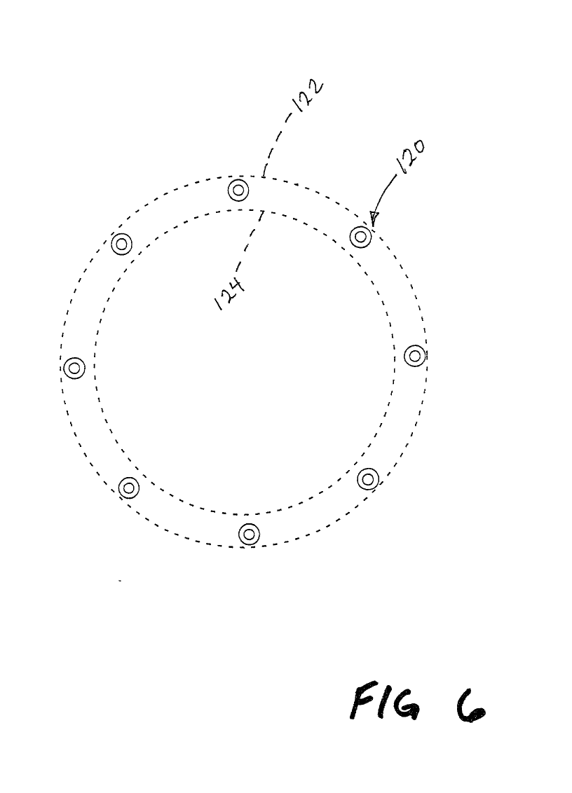

Another configuration of the invention uses a separation member 100 that is a series of separate shims (a set of stainless steel washers, i.e., 120) configured in a flange bolt hole pattern, shown by the dashed lines 122, 124 in FIG. 6. In this configuration there is no structural element that impedes the sideways flow of gas through the clamped joint between the washers. It has been determined that the beneficial effect of the invention is not dependent on there being a gas seal between the gas distribution plate 30 and the upper body portion 40. Eight washers (i.e., 120) located at bolt holes and through which a set of nickel bolts (not shown) pass, clamp each washer between the outer flange 32 of the gas distribution plate and the corresponding mating surface of the upper body portion 40. The washers 120 create a clamping pad around each bolt (not shown) clamping the gas distribution plate 30 to the upper body portion 40 while simultaneously separating the gas distribution plate 30 from the upper body portion 40. The washer stainless material is a 300 or a 400 series stainless steel of about 0.018 inches (0.457 mm) which withstands process temperatures of 650° C. while providing a small area and relatively low rate of conductive heat transfer through the washer material that is in contact with adjacent surfaces.

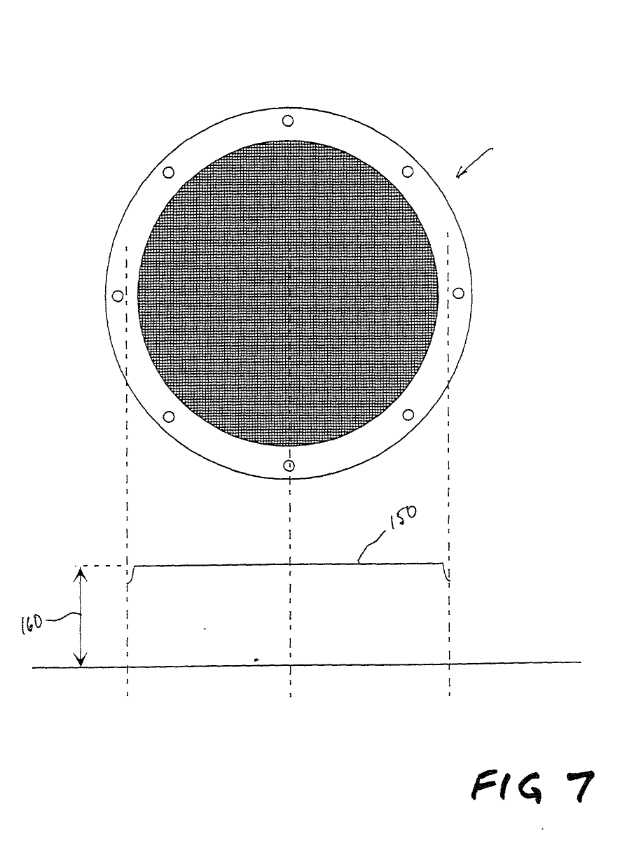

The result of providing a thermal barrier or separation between the faceplate section 34, in particular, and the gas distribution plate 30 as a whole, and the upper body portion 40 is that as the faceplate section 34 facing the heater 62 in the processing chamber rises in temperature, there is a greatly reduced transfer of thermal energy to the “cold” upper body portion 40 that is continuous cooled by a the flow of thermal transfer fluid through its cooling passages 48, so that the upper body portion acts as a heat sink. The minimal conductive heat transfer that occurs promotes a substantially uniform thermal gradient across the face of the faceplate section 34, for example as shown by graph 150 in the lower part of FIG. 7. The magnitude of the temperature level represented by the dimension line 160 represents a generally accurate portrayal of the of a relatively small variation in temperature across the diameter of the gas distribution plate 30 that is experienced when using a configuration according to the present invention. While the curve shown is straight across its middle, this presentation is an idealized case, empirical measurements might show small or large variations in the temperature from the center to the edge. The curve 150 does show a temperature drop off at the edge of the outside flange 32.

The curve 150 can be contrasted with the similarly constructed curve 94 shown in FIG. 3. The variation in temperature from the center to the edge is much less when using a configuration according to the present invention. It is postulated that this small variation in temperature, simply described as a thermally floating faceplate nearly eliminates the transient associated with running in wafers such that steady state thermal conditions are experienced immediately as long as the chamber is heated simultaneously as the chamber is being pumped down. Once process operating conditions, with respect to vacuum conditions are met, no additional time will need to be spent to satisfy thermal conditions so that “production” processing of wafers can begin immediately upon checking a few (3-5) run-in substrates (wafers) to confirm process stability. A graphical illustration of this phenomenon is represented by curve 204 in FIG. 8, where horizontal line 202 represents the approximate value of acceptable measured substrate parameters “X”. Where “X” is one or more parameters that are defined by process conditions and which do not reach acceptable values until they are close to the range of values defined by the line 202.

The invention also includes a method for reducing the number of run-in substrates needed to arrive at steady state processing conditions in a high temperature etch processing chamber comprising the steps of providing a separation member between the gas distribution faceplate 30, 34 and the surface of the processing chamber 40 to which it is clamped; clamping the gas distribution faceplate 30, 34to the surface of the processing chamber 40 so as to create a separation distance (shim thickness) between the gas distribution faceplate 30, 34 to the surface of the processing chamber; preheating the processing chamber to a near etch process temperature; and processing no more than 25 run-in substrates before confirming the uniformity of etch process operation in the high temperature processing chamber 20. Providing the separation member includes providing shims at selected locations between the faceplate 30, 34 and the surface of the processing chamber 40. The separation member may be a polymer based material gasket between the faceplate 30, 34 and the surface of the processing chamber 40 having material properties substantially similar to Vespel. The step of processing no more than 25 run-in substrates before confirming the uniformity of etch process operation in the high temperature processing chamber may include the step of processing no more than 20 or 15 or 10 or 5 run-in substrates before confirming the uniformity of etch process operation in the high temperature processing chamber.

While the invention has been described with specific embodiments, those skilled in the art will recognize that changes can be made in form and detail without departing from the spirit and the scope of the invention.

1. An etch processing chamber comprising:
a heater having a substrate support surface on which a back side of said substrate to be etched is supported during etching of a front side of said substrate;
a gas box cavity in a portion of said etch processing chamber, said cavity being disposed opposite said substrate support surface of said heater;
a gas distribution faceplate disposed between said gas box cavity and said substrate support surface of said heater, said faceplate having gas distribution holes therein to permit the passage of gas therethrough; and
a thermally insulating connection assembly fixing said gas distribution faceplate to said etch processing chamber while providing a substantially minimal transfer of thermal energy by conductive heat transfer between said faceplate and said etch chamber.

2. The etch processing chamber as in claim 1,
wherein said thermally insulating connection assembly includes a series of shims clamped at selected locations between said gas distribution faceplate and said etch processing chamber, wherein said shims act as spacers separating said gas distribution faceplate from said etch processing chamber.

3. The etch processing chamber as in claim 2,
wherein said shims are stainless steel washers.

4. The etch processing chamber as in claim 3,
wherein said stainless steel washers are clamped at selected intervals around a perimeter of said gas distribution faceplate.

5. The etch processing chamber as in claim 1,
wherein said thermally insulating connection assembly includes a polymer based gasket clamped between said gas distribution faceplate and said etch processing chamber, wherein said gasket acts as a spacer separating said gas distribution faceplate from said etch processing chamber.

6. The etch processing chamber as in claim 5,
wherein said polymer based gasket is a gasket made of a material having material properties substantially similar to Vespel.

7. The etch processing chamber as in claim 5,
wherein said gasket is configured to be disposed at a perimeter of said gas distribution faceplate and act as a barrier to the passage of gas at the location of said gasket between said gas box cavity and a process chamber location outside of said gas box cavity.

8. The etch processing chamber as in claim 6,
wherein said gasket is configured to be disposed at a perimeter of said gas distribution faceplate and act as a barrier to the passage of gas at the location of said gasket between said gas box cavity and a process chamber location outside of said gas box cavity.

9. The etch processing chamber as in claim 6,
wherein said gasket has a thickness between 0.010 and 0.030 inches.

10. The etch processing chamber as in claim 9,
wherein said gasket has a thickness of approximately 0.018 inches.

11. An etch processing chamber comprising:
a heater having a substrate support surface on which a back side of said substrate to be etch ed is supported during etching of a front side of said substrate;
a gas box cavity in a portion of said etch processing chamber, said cavity being disposed opposite said substrate support surface of said heater;
a gas distribution faceplate disposed between said box cavity and said substrate support surface of said heater, said faceplate having gas distribution holes therein to permit the passage of gas therethrough; and
a separation member clamped between a surface of said gas distribution faceplate and a surface of said etch processing chamber creating a separation member separation distance between said surface of said gas distribution faceplate and said surface of said etch processing chamber such that because of the presence of said separation member a faceplate separation distance exists between all metal surfaces of said faceplate and all metal surfaces of said processing chamber, except those metal surfaces clamping said faceplate to said processing chamber.

12. The etch processing chamber as in claim 11,
wherein said separation member includes a series of shims clamped at selected locations between said gas distribution faceplate and said etch processing chamber, wherein said shims act as spacers separating said gas distribution faceplate from said etch processing chamber.

13. The etch processing chamber as in claim 12,
wherein said shims are stainless steel washers.

14. The etch processing chamber as in claim 13,
wherein said stainless steel washers are clamped at selected intervals around a perimeter of said gas distribution faceplate.

15. The etch processing chamber as in claim 11,
wherein said separation member includes a polymer based gasket clamped between said gas distribution faceplate and said etch processing chamber, wherein said gasket acts as a spacer separating said gas distribution faceplate from said etch processing chamber.

16. The etch processing chamber as in claim 15,
wherein said polymer based gasket is a gasket made of a material having material properties substantially similar to Vespel.

17. The etch processing chamber as in claim 15,
wherein said gasket is configured to be disposed at a perimeter of said gas distribution faceplate and act as a barrier to the passage of gas at the location of said gasket between said gas box cavity and a process chamber location outside of said gas box cavity.

18. The etch processing chamber as in claim 16,
wherein said gasket is configured to be disposed at a perimeter of said gas distribution faceplate and act as a barrier to the passage of gas at the location of said gasket between said gas box cavity and a process chamber location outside of said gas box cavity.

19. The etch processing chamber as in claim 16,
wherein said gasket has a thickness between 0.010 and 0.030 inches.

20. The etch processing chamber as in claim 19,
wherein said gasket has a thickness of approximately 0.018 inches.

21. An etch processing chamber for processing substrates at temperatures in excess of 550° C. comprising:
a heater having a substrate support surface on which a back side of said substrate to be etched is supported during etching of a front side of said substrate;
a gas box cavity in a portion of said etch processing chamber, said cavity being disposed opposite said substrate support surface of said heater;
a gas distribution faceplate disposed between said gas box cavity and said substrate support surface of said heater, said faceplate having gas distribution holes therein to permit the passage of gas therethrough; and
a thermally insulating connection assembly fixing said gas distribution faceplate to said etch processing chamber while providing a substantially minimal transfer of thermal energy by conductive heat transfer between said faceplate and said etch chamber

22. The etch processing chamber for processing substrates at temperatures in excess of 550° C. as in claim 21,
wherein said thermally insulating connection assembly includes a series of shims clamped at selected locations between said gas distribution faceplate and said etch processing chamber, wherein said shims act as spacers separating said gas distribution faceplate from said etch processing chamber.

23. The etch processing chamber for processing substrates at temperatures in excess of 550° C. as in claim 22,
wherein said shims are stainless steel washers.

24. The etch processing chamber for processing substrates at temperatures in excess of 550° C. as in claim 23,
wherein said stainless steel washers are clamped at selected intervals around a perimeter of said gas distribution faceplate.

25. The etch processing chamber for processing substrates at temperatures in excess of 550° C. as in claim 21,
wherein said thermally insulating connection assembly includes a polymer based gasket clamped between said gas distribution faceplate and said etch processing chamber, wherein said gasket acts as a spacer separating said gas distribution faceplate from said etch processing chamber.

26. The etch processing chamber for processing substrates at temperatures in excess of 550° C. as in claim 25,
wherein said polymer based gasket is a gasket made of a material having material properties substantially similar to Vespel.

27. The etch processing chamber for processing substrates at temperatures in excess of 550° C. as in claim 25,
wherein said gasket is configured to be disposed at a perimeter of said gas distribution faceplate and act as a barrier to the passage of gas at the location of said gasket between said gas box cavity and a process chamber location outside of said gas box cavity.

28. The etch processing chamber for processing substrates at temperatures in excess of 550° C. as in claim 26,
wherein said gasket is configured to be disposed at a perimeter of said gas distribution faceplate and act as a barrier to the passage of gas at the location of said gasket between said gas box cavity and a process chamber location outside of said gas box cavity.

29. The etch processing chamber for processing substrates at temperatures in excess of 550° C. as in claim 26,
wherein said gasket has a thickness between 0.010 and 0.030 inches.

30. The etch processing chamber for processing substrates at temperatures in excess of 550° C. as in claim 29,
wherein said gasket has a thickness of approximately 0.018 inches.

31. A method for reducing the number of run-in substrates needed to arrive at steady state process conditions in a high temperature etch processing chamber comprising the steps of:
providing a separation member between a gas distribution faceplate and a surface of said processing chamber to which it is clamped;
clamping said gas distribution faceplate to said surface of said processing chamber so as to create a separation distance between said gas distribution faceplate to said surface of said processing chamber;
preheating said processing chamber to a near etch process temperature; processing no more than 25 run-in substrates before confirming the uniformity of etch process operation in said high temperature processing chamber.

32. The method for reducing the number of run-in substrates needed to arrive at steady state process conditions in a high temperature etch processing chamber as in claim 31,
wherein the step of providing said separation member includes providing shims at selected locations between said faceplate and said surface of said processing chamber.

33. The method for reducing the number of run-in substrates needed to arrive at steady state process conditions in a high temperature etch processing chamber as in claim 31,
wherein the step of providing said separation member includes providing a polymer based material gasket between said faceplate and said surface of said processing chamber.

34. The method for reducing the number of run-in substrates needed to arrive at steady state process conditions in a high temperature etch processing chamber as in claim 31,
wherein said polymer based material is a material having properties substantially similar to Vespel.

35. The method for reducing the number of run-in substrates needed to arrive at steady state process conditions in a high temperature etch processing chamber as in claim 31 wherein the step of processing no more than 25 run-in substrates before confirming the uniformity of etch process operation in said high temperature processing chamber, includes the step of processing no more than 20 run-in substrates before confirming the uniformity of etch process operation in said high temperature processing chamber.

36. The method for reducing the number of run-in substrates needed to arrive at steady state process conditions in a high temperature etch processing chamber as in claim 31 wherein the step of processing no more than 25 run-in substrates before confirming the uniformity of etch process operation in said high temperature processing chamber, includes the step of processing no more than 15 run-in substrates before confirming the uniformity of etch process operation in said high temperature processing chamber.

37. The method for reducing the number of run-in substrates needed to arrive at steady state process conditions in a high temperature etch processing chamber as in claim 31 wherein the step of processing no more than 25 run-in substrates before confirming the uniformity of etch process operation in said high temperature processing chamber, includes the step of processing no more than 10 run-in substrates before confirming the uniformity of etch process operation in said high temperature processing chamber.

38. The method for reducing the number of run-in substrates needed to arrive at steady state process conditions in a high temperature etch processing chamber as in claim 31 wherein the step of processing no more than 25 run-in substrates before confirming the uniformity of etch process operation in said high temperature processing chamber, includes the step of processing no more than 5 run-in substrates before confirming the uniformity of etch process operation in said high temperature processing chamber.
